(19) United States
(12) Patent Application Publication
(10) Pub. No.: US 2024/0421223 A1
(43) Pub. Date: Dec. 19, 2024

(54) SEMICONDUCTOR DEVICE

(71) Applicant: Samsung Electronics Co., Ltd., Suwon-si (KR)

(72) Inventors: Joongchan SHIN, Suwon-si (KR); Seokhan PARK, Suwon-si (KR); Kiseok LEE, Suwon-si (KR); Moonyoung JEONG, Suwon-si (KR); Jinwoo HAN, Suwon-si (KR)

(73) Assignee: Samsung Electronics Co., Ltd., Suwon-si (KR)

(21) Appl. No.: 18/631,839

(22) Filed: Apr. 10, 2024

(30) Foreign Application Priority Data
Jun. 13, 2023 (KR) 10-2023-0075550

(51) Int. Cl. H01L 29/78; H10B 12/00

(52) U.S. Cl. CPC H01L 29/7827; H10B 12/482; H10B 12/488

(57) ABSTRACT

A semiconductor device includes a substrate, a bit line extending in a first direction on the substrate, a first active pattern and a second active pattern on the bit line, a back gate electrode extending in a second direction perpendicular to the first direction across the bit line, and a word line extending in the second direction, wherein the first active pattern and the second active pattern have a minor symmetrical shape with respect to the back gate electrode when viewed in a third direction perpendicular to the first direction and the second direction.

### CROSS-REFERENCE TO RELATED APPLICATION

This application is based on and claims priority under 35 U.S.C. § 119 to Korean Patent Application No. 10-2023-0075550, filed on Jun. 13, 2023, in the Korean Intellectual Property Office, the disclosure of which is incorporated by reference herein in its entirety.

### BACKGROUND

The inventive concepts relate to semiconductor devices. More specifically, the inventive concepts relate to semiconductor devices including a vertical channel transistor.

In order to satisfy excellent performance and economic feasibility, it is required to increase the degree of integration of semiconductor devices. In particular, the degree of integration of memory devices is a crucial factor in determining the economic feasibility of a product. Since the degree of integration of two-dimensional memory devices is mainly determined by an area occupied by unit memory cells, the degree of integration is greatly affected by the level of fine pattern formation technology. However, since expensive equipment is required to form fine patterns and an area of a chip die is limited, the degree of integration of two-dimensional memory devices is increasing but it is still limited.

### SUMMARY

Some example embodiments of the inventive concepts provide a semiconductor device including a vertical channel transistor with various widths and forms of active patterns.

In addition, the task to be solved by the technical idea of the inventive concepts is not limited to the above-mentioned task, and other tasks not mentioned above may be clearly understood by those of ordinary skill in the art from the following description.

According to some example embodiments of the inventive concepts, there are provided the following semiconductor devices.

According to some example embodiments of the inventive concepts, there is provided a semiconductor device that may include a substrate, a bit line extending in a first direction on the substrate, a first active pattern and a second active pattern on the bit line, a back gate electrode extending in a second direction perpendicular to the first direction across the bit line, and a word line extending in the second direction, wherein the first active pattern and the second active pattern have a minor symmetrical shape with respect to the back gate electrode when viewed in a third direction perpendicular to the first direction and the second direction.

According to some example embodiments of the inventive concepts, there is provided a semiconductor device that may include a substrate, a plurality of bit lines extending in a first direction on the substrate and spaced apart from each other in a second direction perpendicular to the first direction, a plurality of first active patterns and a plurality of second active patterns on the plurality of bit lines, a back gate electrode between the plurality of first active patterns and the plurality of second active patterns and extending in the second direction across the plurality of bit lines, a first word line extending in the second direction on one side of the plurality of first active patterns, and a second word line extending on one side of the plurality of second active patterns in the second direction and spaced apart from the first word line in the first direction with the plurality of first active patterns, the back gate electrode, and the plurality of second active patterns therebetween, wherein each of the plurality of first active patterns and the plurality of second active patterns have a mirror symmetrical shape with respect to the back gate electrode when viewed in a third direction perpendicular to the first direction and the second direction.

According to some example embodiments of the inventive concepts, there is provided a semiconductor device that may include a substrate, a plurality of bit lines extending in a first direction on the substrate and spaced apart from each other in a second direction perpendicular to the first direction, a plurality of first active patterns on the plurality of bit lines, a plurality of second active patterns on the plurality of bit lines, a back gate electrode between the plurality of first active patterns and the plurality of second active patterns and extending in the second direction across the plurality of bit lines, a first word line extending in the second direction on one side of the plurality of first active patterns, a second word line extending on one side of the plurality of second active patterns in the second direction and spaced apart from the first word line in the first direction with the plurality of first active patterns, the back gate electrode, and the plurality of second active patterns therebetween, and a gate insulating pattern surrounding the plurality of first active patterns and the plurality of second active patterns, wherein each of the plurality of first active patterns includes a first surface facing the back gate electrode and a second surface facing the first word line, each of the plurality of second active patterns includes a first surface facing the back gate electrode and a second surface facing the second word line, the second surface of each first active pattern of the plurality of first active patterns comprises a part rounded to gradually approach the back gate electrode as the second surface of the first active pattern approaches opposite ends of the second surface of the first active pattern in the second direction, the second surface of each second active pattern of the plurality of second active patterns comprises a part rounded to gradually approach the back gate electrode as the second surface of the second active pattern approaches opposite ends of the second surface of the second active pattern in the second direction, the first word line includes a first protrusion portion between adjacent first active patterns of the plurality of first active patterns in the second direction, and the second word line includes a second protrusion portion between adjacent second active patterns of the plurality of second active patterns in the second direction.

### BRIEF DESCRIPTION OF THE DRAWINGS

Example embodiments of the inventive concepts will be more clearly understood from the following detailed description taken in conjunction with the accompanying drawings in which:

FIG. 1 is a layout diagram schematically illustrating a semiconductor device according to some example embodiments;

FIG. 2 is a perspective view schematically illustrating a main configuration of the semiconductor device of FIG. 1 according to some example embodiments;

FIG. 3A is a cross-sectional view illustrating a semiconductor device taken along line A to A′ of FIG. 1 according to some example embodiments;

FIG. 3B is a cross-sectional view illustrating a semiconductor device taken along line B to B′ of FIG. 1 according to some example embodiments;

FIGS. 4A and 4B are layout diagrams schematically illustrating a semiconductor device according to some example embodiments;

FIGS. 5A and 5B are layout diagrams schematically illustrating a semiconductor device according to some example embodiments;

FIGS. 6A and 6B are layout diagrams schematically illustrating a semiconductor device according to some example embodiments;

FIGS. 7A and 7B are layout diagrams schematically illustrating a semiconductor device according to some example embodiments; and

FIGS. 8A and 8B are layout diagrams schematically illustrating a semiconductor device according to some example embodiments.

### DETAILED DESCRIPTION

Hereinafter, some example embodiments of the inventive concepts will be described in detail with reference to the accompanying drawings. The same reference numerals are used for the same components in the drawings, and redundant descriptions thereof are omitted.

Throughout the specification, when a part is “connected” to another part, it includes not only a case where the part is “directly connected” but also a case where the part is “indirectly connected” with another part in between. In addition, unless explicitly described to the contrary, the word “comprise” and variations such as “comprises” or “comprising” will be understood to imply the inclusion of stated elements but not the exclusion of any other elements.

It will be understood that when an element such as a layer, film, region, area, or substrate is referred to as being “on” another element, it can be directly on the other element or intervening elements may also be present. In contrast, when an element is referred to as being “directly on” another element, there are no intervening elements present. Further, in the specification, an element that is “on” another element may be above, beneath, or horizontally next to (e.g., horizontally adjacent to) the other element and is not necessarily above an upper side of the other element based on a gravitational direction.

The use of the term “the” and similar demonstratives may correspond to both the singular and the plural. Operations constituting methods may be performed in any suitable order unless otherwise indicated herein or otherwise clearly contradicted by context and are not necessarily limited to the stated order.

The use of all illustrations or illustrative terms in some example embodiments is simply to describe the technical ideas in detail, and the scope of the present inventive concepts is not limited by the illustrations or illustrative terms unless they are limited by claims.

It will be understood that elements and/or properties thereof (e.g., structures, surfaces, directions, or the like), which may be referred to as being “perpendicular,” “parallel,” “coplanar,” or the like with regard to other elements and/or properties thereof (e.g., structures, surfaces, directions, or the like) may be “perpendicular,” “parallel,” “coplanar,” or the like or may be “substantially perpendicular,” “substantially parallel,” “substantially coplanar,” respectively, with regard to the other elements and/or properties thereof.

Elements and/or properties thereof (e.g., structures, surfaces, directions, or the like) that are “substantially perpendicular”, “substantially parallel”, or “substantially coplanar” with regard to other elements and/or properties thereof will be understood to be “perpendicular”, “parallel”, or “coplanar”, respectively, with regard to the other elements and/or properties thereof within manufacturing tolerances and/or material tolerances and/or have a deviation in magnitude and/or angle from “perpendicular”, “parallel”, or “coplanar”, respectively, with regard to the other elements and/or properties thereof that is equal to or less than 10% (e.g., a. tolerance of ±10%).

It will be understood that elements and/or properties thereof may be recited herein as being “the same” or “equal” as other elements, and it will be further understood that elements and/or properties thereof recited herein as being “identical” to, “the same” as, or “equal” to other elements may be “identical” to, “the same” as, or “equal” to or “substantially identical” to, “substantially the same” as or “substantially equal” to the other elements and/or properties thereof. Elements and/or properties thereof that are “substantially identical” to, “substantially the same” as or “substantially equal” to other elements and/or properties thereof will be understood to include elements and/or properties thereof that are identical to, the same as, or equal to the other elements and/or properties thereof within manufacturing tolerances and/or material tolerances. Elements and/or properties thereof that are identical or substantially identical to and/or the same or substantially the same as other elements and/or properties thereof may be structurally the same or substantially the same, functionally the same or substantially the same, and/or compositionally the same or substantially the same. While the term “same,” “equal” or “identical” may be used in description of some example embodiments, it should be understood that some imprecisions may exist. Thus, when one element is referred to as being the same as another element, it should be understood that an element or a value is the same as another element within a desired manufacturing or operational tolerance range (e.g., ±10%).

It will be understood that elements and/or properties thereof described herein as being “substantially” the same and/or identical encompasses elements and/or properties thereof that have a relative difference in magnitude that is equal to or less than 10%. Further, regardless of whether elements and/or properties thereof are modified as “substantially,” it will be understood that these elements and/or properties thereof should be construed as including a manufacturing or operational tolerance (e.g., ±10%) around the stated elements and/or properties thereof.

When the terms “about” or “substantially” are used in this specification in connection with a numerical value, it is intended that the associated numerical value includes a manufacturing or operational tolerance (e.g., ±10%) around the stated numerical value. Moreover, when the words “about” and “substantially” are used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., ±10%) around the stated numerical values or shapes. When ranges are specified, the range includes all values therebetween such as increments of 0.1%.

As described herein, when an operation is described to be performed, or an effect such as a structure is described to be established “by” or “through” performing additional operations, it will be understood that the operation may be performed and/or the effect/structure may be established “based on” the additional operations, which may include performing said additional operations alone or in combination with other further additional operations.

As described herein, an element that is described to be “spaced apart” from another element, in general and/or in a particular direction (e.g., vertically spaced apart, laterally spaced apart, etc.) and/or described to be “separated from” the other element, may be understood to be isolated from direct contact with the other element, in general and/or in the particular direction (e.g., isolated from direct contact with the other element in a vertical direction, isolated from direct contact with the other element in a lateral or horizontal direction, etc.). Similarly, elements that are described to be “spaced apart” from each other, in general and/or in a particular direction (e.g., vertically spaced apart, laterally spaced apart, etc.) and/or are described to be “separated” from each other, may be understood to be isolated from direct contact with each other, in general and/or in the particular direction (e.g., isolated from direct contact with each other in a vertical direction, isolated from direct contact with each other in a lateral or horizontal direction, etc.). Similarly, a structure described herein to be between two other structures to separate the two other structures from each other may be understood to be configured to isolate the two other structures from direct contact with each other.

Since the example embodiments may apply various conversions and have some example embodiments, some example embodiments will be illustrated in the drawings and described in detail. However, this is not intended to limit the scope for any particular example embodiment, and should be understood to include all transformations, equivalents, or substitutes included in the scope of the disclosed ideas and technologies. In describing some example embodiments, when it is determined that a detailed description of the related known technology may obscure the gist, a detailed description thereof will be omitted.

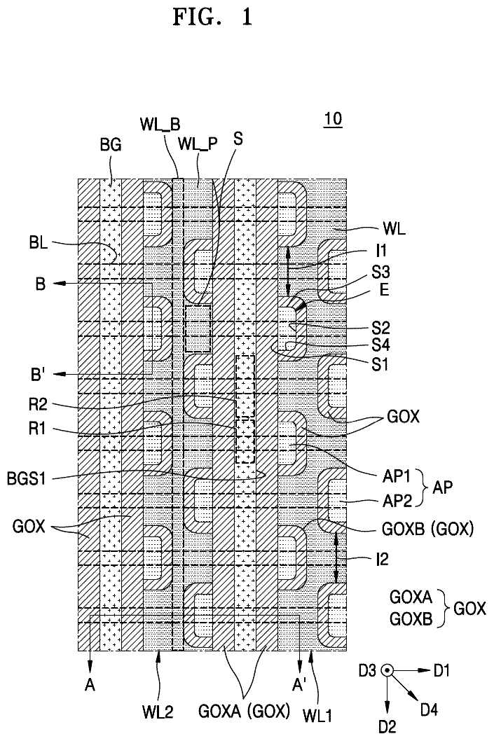

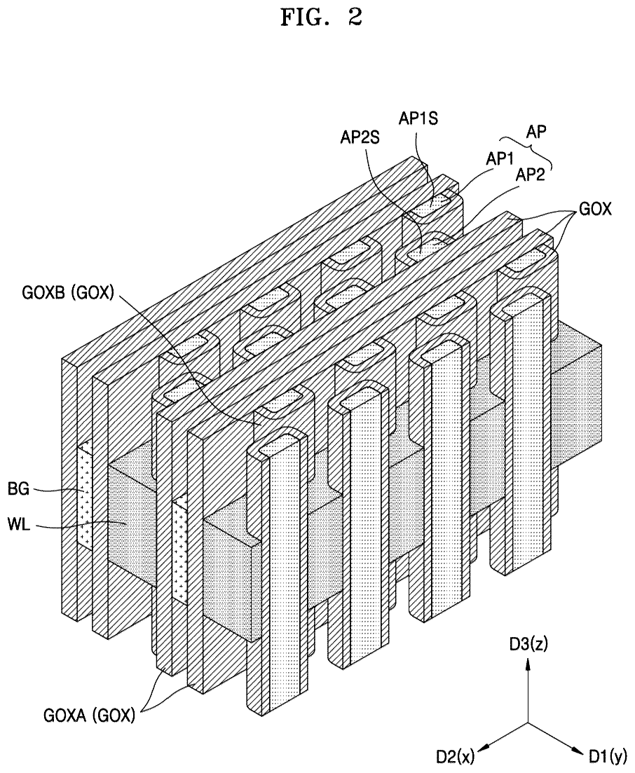

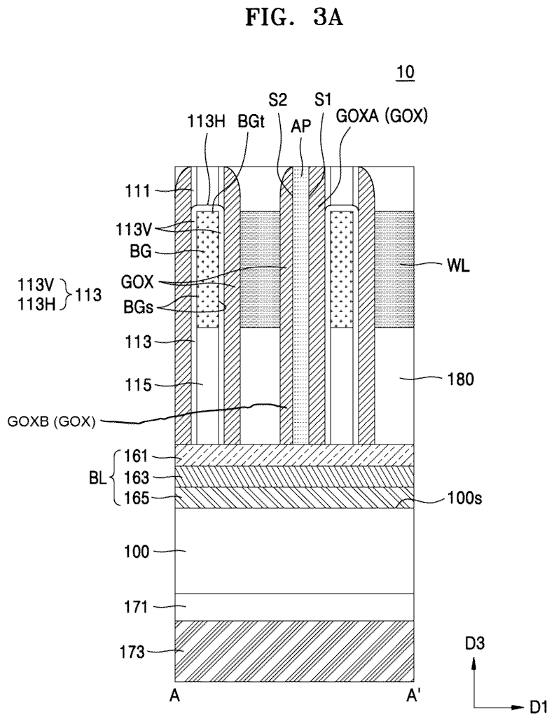

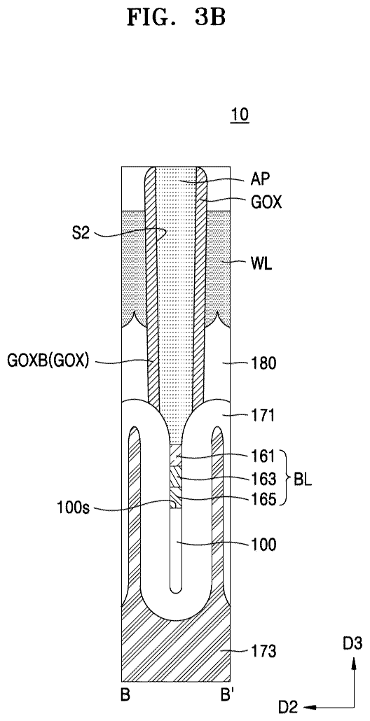

FIG. 1 is a layout diagram schematically illustrating a semiconductor device according to some example embodiments. FIG. 2 is a perspective view schematically illustrating a main configuration of the semiconductor device of FIG. 1. FIG. 3A is a cross-sectional view illustrating a semiconductor device taken along line A to A′ of FIG. 1, and FIG. 3B is a cross-sectional view illustrating a semiconductor device taken along line B to B′ of FIG. 1.

Referring to FIGS. 1, 2, 3A, and 3B, the semiconductor device may include a substrate 100, a plurality of bit lines BL, an active pattern AP, a plurality of back gate electrodes BG, and a plurality of word lines WL.

The substrate 100 of the semiconductor device 10 may have a structure in which a base substrate and an epitaxial layer are stacked, but the technical idea of the inventive concepts is not limited thereto. For example, the substrate 100 may be a silicon substrate, a gallium arsenide substrate, a silicon germanium substrate, or a semiconductor on insulator (an) substrate. For example, the substrate 100 will be described below as a silicon substrate.

The bit line BL of the semiconductor device 10 may extend in the first direction D1 on the substrate 100. A plurality of bit lines BL may be spaced apart from each other in the second direction D2 which may be perpendicular to the first direction. The bit line BL may include a polysilicon pattern 161, a metal pattern 163, and a hard mask pattern 165, which are sequentially stacked. Here, the hard mask patterns 165 of the bit lines BL may be in contact with the substrate 100. The metal pattern 163 may include a conductive metal nitride (e.g., titanium nitride or tantalum nitride) or a metal (e.g., tungsten, titanium, or tantalum). In some example embodiments, the metal pattern 163 may include a metal silicide such as titanium silicide, cobalt silicide, or nickel silicide. The hard mask pattern 165 may include an insulating material such as silicon nitride or silicon oxynitride.

In some example embodiments, the semiconductor device 10 may include gap structures 173 located on both sides (e.g., opposite sides) of the bit line BL. Each of the gap structures 173 may be surrounded by an insulating layer 171 The insulating layer 171 may include silicon oxide, silicon oxynitride, a high dielectric material with a higher dielectric constant than silicon oxide, or any combination thereof. The gap structures 173 may extend side-by-side in the first direction Dl.

In some example embodiments, the gap structures 173 may be made of a conductive material. However, the technical idea of the inventive concepts is not limited thereto, and the semiconductor device 10 according to the inventive concepts may not necessarily include gap structures 173.

The active pattern AP of the semiconductor device 10 may be arranged on the plurality of bit lines BL. The active pattern AP may have a width in the first direction D1, a thickness in the second direction D2 perpendicular to the first direction D1, and a height in the third direction D3 perpendicular to the substrate 100.

The active pattern AP may include a first active pattern AP1 and a second active pattern AP2. The first active pattern AP1 and the second active pattern AP2 may be alternately arranged on each bit line BL in an arbitrary direction diagonal to the first direction D1 (e.g., a diagonal direction D4). By arranging the first active pattern AP1 and the second active pattern AP2 in the diagonal direction, the degree of integration of the semiconductor device 10 in the first direction D1 may be improved, As described herein, improved integration of a semiconductor device may further improve miniaturization and compactness of the semiconductor device and any devices including same. A plurality of first active patterns AP1 may be spaced apart from each other at a particular (or, alternatively, predetermined) interval I1 in the second direction D2, and a plurality of second active patterns AP2 may be spaced apart from each other at a particular (or, alternatively, predetermined) interval I2 in the second direction D2. In other words, the first active pattern AP1 and the second active pattern AP2 may be two-dimensionally arranged in the first direction D1 and the second direction D2 crossing each other. The shape of the first active pattern AP1 may have a minor symmetrical shape with respect to the shape of the second active pattern AP2 based on the back gate electrode BG. The second interval I2 may be a same interval (e.g., have a same magnitude) as the first interval I1. As shown in at least FIG. 2, an uppermost surface AP1S (e.g., a top surface) of the first active pattern AP1 in the third direction D3 may be coplanar with an uppermost surface AP2S (e.g., a top surface) of the second active pattern AP2 in the third direction D3.

A length of the active pattern AP in the second direction D2 (e.g., a length of each of the first active pattern AP1 and the second active pattern AP2 in the second direction D2) may be greater than a length of the bit line in the second direction D2. That is, the thickness of the active pattern AP may be greater than the thickness of the bit line BL. In some example embodiments, the active pattern AP may have rounded edges. In some example embodiments, the active pattern AP may be made of a single crystal semiconductor material, but the technical idea of the inventive concepts is not limited thereto.

The active pattern AP may include a first dopant region adjacent to the bit line BL, a second dopant region spaced apart from the first dopant region in the third direction D3, and a channel region between the first dopant region and the second dopant region. For example, the first dopant region may be referred to as a source region, and the second dopant region may be referred to as a drain region. The channel region of the active pattern AP may be controlled by the word line WL and the back gate electrode BG at the time of operation of the semiconductor device 10.

The back gate electrode BG of the semiconductor device 10 may extend in the second direction D2 perpendicular to the first direction D1 across the bit line BL. The back gate electrode BG may be arranged between the first active pattern AP1 and the second active pattern AP2 (e.g., between the first active pattern AP1 and the second active pattern AP2 in the first direction D1). The back gate electrode BG may have a height in the third direction D3 that is less than the height of the active pattern AP in the third direction D3. A plurality of back gate electrodes BG may be arranged to be spaced apart from each other in the first direction D1. In some example embodiments, the first direction D1 and the second direction D2 may be understood to extend in parallel with an in-plane direction of the substrate 100 or a surface 100s (e.g., upper surface, lower surface, etc.) of the substrate 100 and perpendicular to each other, and the third direction D3 may be understood to extend perpendicular to the in-plane direction of the substrate 100 or the surface 100s of the substrate 100 and further perpendicular to the first and second directions D1 and D2, but example embodiments are not limited thereto.

In some example embodiments, the back gate electrode BG of the semiconductor device 10 may include a first region in which the active pattern AP is located on one side and a second region in which the active pattern is not located on one side when the cross-section of the back gate electrode BG is viewed with respect to the first direction D1. For example, as shown in FIG. 1, the back gate electrode BG may include a first region R1 in which an active pattern (e.g., a first active pattern AP1) is on one side BGS1 of the back gate electrode BG in the first direction D1 and a second region R2 in which the active pattern (e.g., the first active pattern AP1) is not located on the one side BGS1, for example such that the one side BGS1 may be exposed from the first active pattern AP1 in the first direction D1 in the second region R2.

For example, the back gate electrode BG may include doped polysilicon, conductive metal nitride (e.g., titanium nitride or tantalum nitride), metal (e.g., tungsten, titanium, or tantalum), conductive metal silicide, conductive metal oxide, or any combination thereof.

The first insulating pattern 111 may be arranged on one side of the active pattern AP. The first insulating pattern 111 may be arranged on one side of the second dopant region of the active pattern AP. The first insulating pattern 111 may extend in parallel to the back gate electrodes BG in the first direction D1. For example, the first insulating pattern 111 may include a silicon oxide layer, a silicon oxynitride layer, or a silicon nitride layer.

The back gate insulating pattern 113 each may be arranged between the back gate electrode BG and the active pattern AP and between the back gate electrode BG and the first insulation pattern 111. The back gate insulating pattern 113 may include vertical portions 113V covering both sides (e.g., opposite sides) BGs of the back gate electrode BG and a horizontal portion 113H connecting the vertical portions 113V. The horizontal portion of the back gate insulating pattern 113 may cover a top surface BGt of the back gate electrode BG. For example, the back gate insulating pattern 113 may include a silicon oxide film, a silicon oxynitride film, a high dielectric film with a higher dielectric constant than the silicon oxide film, or any combination thereof.

A back gate capping pattern 115 may be arranged between the bit line BL and the back gate electrode BG. The back gate capping pattern 115 may be made of an insulating material, and a bottom surface of the back gate capping pattern 115 may contact the polysilicon pattern 161 of the bit lines BL. The back gate capping pattern 115 may be arranged between vertical portions 113V of the back gate insulating pattern 113.

The word line WL of the semiconductor device 10 may extend in the second direction D2 across the bit line BL and on the bit line BL. The word line WL may be arranged on the other side (e.g., the opposite side) of the active pattern AP in relation to the back gate electrode BG. That is, the back gate electrode BG may be arranged on one side of the active pattern AP, and the word line WL may be arranged on the other side (e.g., an opposite side) of the active pattern AP. As shown, a first word line WL1 may extend in the second direction D2 on (e.g., adjacent to) one side of a plurality of first active patterns AP1 and a second word line WL2 extending on (e.g., adjacent to) one side of a plurality of second active patterns AP2 in the second direction D2 and spaced apart from the first word line WL1 in the first direction D1 with the plurality of first active patterns AP1, a back gate electrode GE, and the plurality of second active patterns AP2 therebetween.

The word line WL may be vertically spaced apart from the bit line BL (e.g., in the third direction D3). In other words, from a vertical viewpoint, an insulating layer (e.g., insulating layer 180) may be positioned between the bit lines BL and the word line WL (e.g., in the third direction D3). The insulating layer 180 may include silicon oxide, silicon oxynitride, a high dielectric material with a higher dielectric constant than silicon oxide, or any combination thereof.

For example, the word lines WL may include doped polysilicon, metal, conductive metal nitride, conductive metal silicide, conductive metal oxide, or any combination thereof.

Gate insulating patterns GOX may be arranged between the word line WL and the active pattern AP. As shown, the gate insulating patterns GOX may surround (e.g., completely surround in a plane extending in the first and second directions D1 and D2) the first active pattern AP1 and the second active pattern AP2. The gate insulating patterns GOX may extend in parallel to the word line WL in the second direction D2. In some example embodiments, at least a portion of the gate insulating patterns GOX may be arranged between the word line WL and the back gate electrode BG and may extend in parallel to the back gate electrode BG in the second direction D2. As shown in at least FIGS. 1, 2, and 3A, a gate insulating pattern GOX may include a first gate insulating pattern GOXA and a second gate insulating pattern GOXB. The first gate insulating pattern GOXA may be between a back gate electrode BG and the active pattern AP, for example between the active pattern AP and both the back gate insulating pattern 113 and the first insulation pattern 111. The second gate insulating pattern GOXB may be between (e.g., directly between) the active pattern AP and word line WL. In some example embodiments, the first gate insulating pattern GOXA of the gate insulating patterns GOX may be omitted, such that the active pattern AP may be in contact with the back gate insulating pattern 113 and the first insulation pattern 111.

The gate insulating pattern GOX or any portion thereof (e.g., the first gate insulating pattern GOXA and/or the second insulating pattern GOXB) may include a silicon oxide film, a silicon oxynitride film, a high dielectric film with a higher dielectric constant than the silicon oxide film, or any combination thereof. The high dielectric film may be made of a metal oxide or a metal oxynitride. For example, the high dielectric film that may be used as a gate insulating pattern GOX may include HfO₂, HfSiO, HfSiON, HfTaO, HfSiO, HfZrO, ZrO₂, Al₂O₃, or any combination thereof but is not limited thereto.

The active pattern AP of the semiconductor device 10 may include a first surface S1 facing the back gate electrode BG and a second surface S2 facing the word line WL. In some example embodiments, the first surface S1 of the active pattern AP may be in contact with at least a portion of the first gate insulating pattern of the GOXA of the gate insulating patterns GOX and the second surface S2 of the active pattern AP may be in contact with the second gate insulating pattern GOXB of the gate insulating patterns GOX. In some example embodiments, where a gate insulating pattern GOX omits the first gate insulating pattern GOXA shown in FIGS. 1, 2, and 3A and is formed of at least the second gate insulating pattern GOXB shown in FIGS. 1, 2, and 3A-3B, the first surface S1 of the active pattern AP may be in contact with the back gate insulating pattern 113 (e.g., in contact with the back gate insulating pattern 113 alone or in combination with the first insulating pattern 111), and the second surface S2 of the active pattern AP may be in contact with the gate insulating pattern GOX (e.g., in contact with the second gate insulating pattern GOXB).

An edge E of the active pattern AP, which is in contact with a gate insulating pattern GOX among edges of the active pattern AP and extends in a third direction, may be rounded (see FIGS. 1 and 2). That is, when the active pattern AP is viewed in a plane (e.g., a plane extending in the first and second directions D1 and D2 as shown in FIG. 1), a side facing the word line WL may have a rounded shape. In other words, the active pattern may include a third surface S3 and a fourth surface S4 perpendicular to the second surface S2 and spaced apart from each other in the second direction D2 and which may be connected to the second surface S2 in a curved line. In some example embodiments, the edge E where the second surface S2 and the third surface S3 meet may be a round surface that extends longitudinally in the third direction D3 and has a particular (or, alternatively, predetermined) curvature.

In some example embodiments, the second surface S2 may be a curved surface convex toward the word line WL, and the first surface S1 thereof may be a plane (e.g., a plane extending in the second direction D2 and the third direction D3). In other words, the active pattern AP may have a shape in which the thickness of the shape decreases to the second surface from the first surface.

The gate insulating pattern GOX may be formed of a single film. That is, the gate insulating pattern GOX may be the same film in a region in contact with the second surface S2 of the active pattern AP and a region in contact with the third surface S3 and the fourth surface S4 of the active pattern AP. However, the gate insulating pattern GOX may not be a single film formed and obtained at a time, and sequences formed according to a process may be different from each other.

The word line WL of the semiconductor device 10 may protrude from a body WL_B extending lengthily (e.g., longitudinally) in the first direction D1 and may include a protrusion WL_P located on the third or fourth surface S3 or S4 of the active pattern AP. In other words, the word line WL may surround the second to fourth surfaces S2 to S4 of the active pattern AP.

In some example embodiments, the gate insulating pattern GOX (e.g., at least the second gate insulating pattern GOXB of the gate insulating pattern GOX) may be formed on the active pattern AP having a rounded shape at a substantially constant width. The word line WL is formed on the gate insulating pattern GOX, and the word line WL may have a rounded shape at a portion where the protrusion WL_P protrudes from the body WL_B. That is, in a plane view of the word line WL, the protrusion WL_P may have a rounded shape in a region protruding from the body WL_B. In other words, among edges where the protrusion WL_P and the body WL_B contact each other, an edge extending in the third direction D3 may have a constant curvature. As shown, the protrusion WL_P may fill a space S between adjacent first active patterns AP1 of the plurality of first active patterns AP1, a space S between adjacent second active patterns AP2 of the plurality of second active patterns AP2, or any combination thereof. In some example embodiments, in an etching process of the active pattern AP, a particular (or, alternatively, predetermined) edge of the active pattern AP may be formed to be rounded. For example, the second surface S2 of each first active pattern AP1 may comprise a part rounded to gradually approach the back gate electrode BG (e.g., to gradually approach the back gate electrode BG in the first direction D1) as the second surface S2 of the first active pattern AP1 approaches opposite ends of the second surface S2 of the first active pattern AP1 in the second direction D2, and the second surface S2 of each second active pattern AP2 may comprise a part rounded to gradually approach the back gate electrode BG (e.g., to gradually approach the back gate electrode BG in the first direction D1) as the second surface S2 of the second active pattern AP2 approaches opposite ends of the second surface S2 of the second active pattern AP2 in the second direction D2. In addition, the gate insulating pattern GOX (e.g., portion GOXB of the gate insulating pattern GOX) with a certain thickness is formed on the active pattern AP with a rounded shape, so the gate insulating pattern GOX (e.g., at least portion GOXB of the gate insulating pattern GOX) may have a rounded shape along the rounded shape of the active pattern AP. A particular (or, alternatively, predetermined) edge of the sidewall of the word line WL formed on the gate insulating pattern GOX (e.g., on at least the portion GOXB of the gate insulating pattern GOX) may also be rounded. However, the technical idea of the inventive concepts is not limited thereto, and the edges of the active pattern AP may be angular without rounding.

Hereinafter, some example embodiments of the semiconductor device according to the inventive concepts will be described with reference to the drawings.

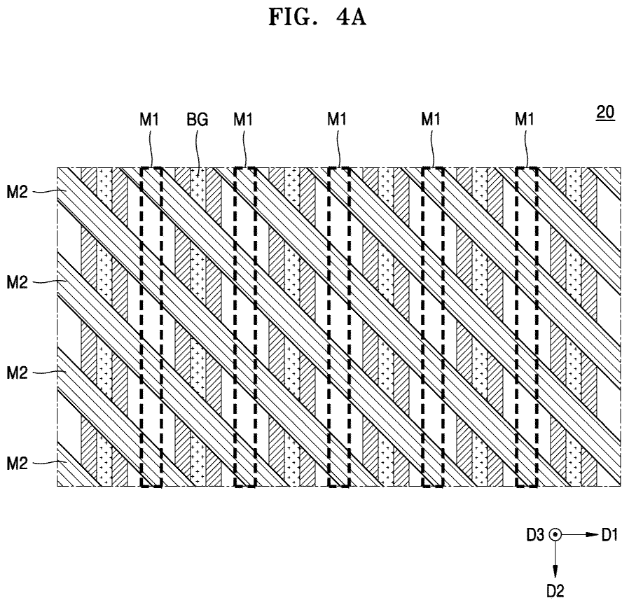

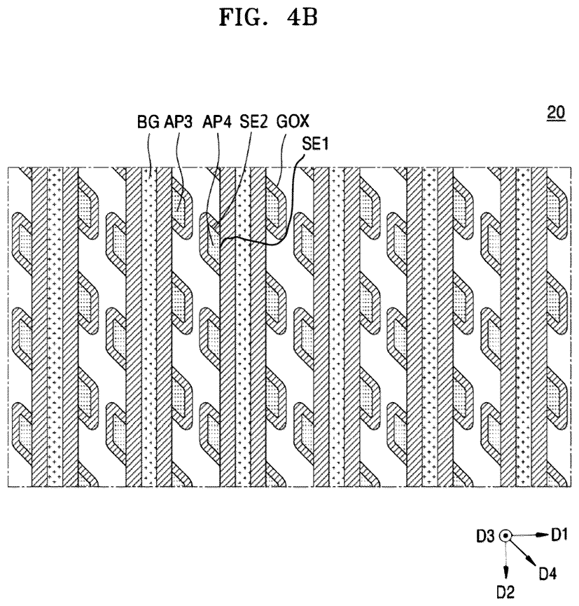

FIGS. 4A and 4B are layout diagrams schematically illustrating a semiconductor device 20 according to some example embodiments. Specifically, FIG. 4A is a layout diagram before etching an active pattern by covering a self-aligned mask M1 and a channel cut mask M2 after forming a back gate electrode BG, and FIG. 4B is a layout diagram after etching the active pattern AP and forming even a gate insulating pattern surrounding the active pattern in FIG. 4A.

Referring to FIGS. 4A and 4B, redundant description between the semiconductor device 20 of FIGS. 4A and 4B and the semiconductor device 10 of FIG. 1 will be omitted, and differences therebetween will be mainly explained.

The active pattern AP of the semiconductor device 20 may include a third active pattern AP3 and a fourth active pattern AP4. The shapes of the third active pattern AP3 and the fourth active pattern AP4 finally formed in FIG. 4B may be determined by the shapes of the self-aligned mask M1 and the channel cut mask M2 shown in FIG. 4A. The self-aligned masks M1 may be formed in a bar shape parallel to the second direction D2. The channel cut mask M2 may be formed in a bar shape parallel to a direction diagonal to the second direction D2.

The third active pattern AP3 and the fourth active pattern AP4 may be alternately arranged on each bit line BL to face each other in a direction diagonal to the first direction D1. That is, the third active pattern AP3 and the fourth active pattern AP4 adjacent to each other may be arranged in a diagonal direction D4 on the bit line BL when viewed from a plane (e.g., a diagonal direction to the first direction D1 and/or the second direction D2).

That is, the first surface and the second surface of the third active pattern AP3 may not completely overlap each other in terms of the first direction D1. The first surface and the second surface of the fourth active pattern AP4 may not completely overlap each other in terms of the first direction D1. By arranging the third active pattern AP3 and the fourth active pattern AP4 in the diagonal direction, the degree of integration of the semiconductor device 20 in the first direction D1 may be improved.

The third active pattern AP3 and the fourth active pattern AP4 may have a parallelogram shape when viewed from a plane (e.g., a plane extending in the first direction D1 and the second direction D2). The third active pattern AP3 and the fourth active pattern AP4 may include a first side SE1 parallel to the second direction D2 and a second side SE2 parallel to the direction D4 diagonal to the first direction D1. In some example embodiments, and as shown in FIG. 4B, the first side S1 may be longer than the second side SE2 (e.g., a length of the first side SE1 in the second direction D2 is greater than a length of the second side SE2 in the diagonal direction D4). In some example embodiments, the length of each of the second side of the third active pattern AP3 and the fourth active pattern AP4 may be greater than the length of the bit line BL in the second direction D2.

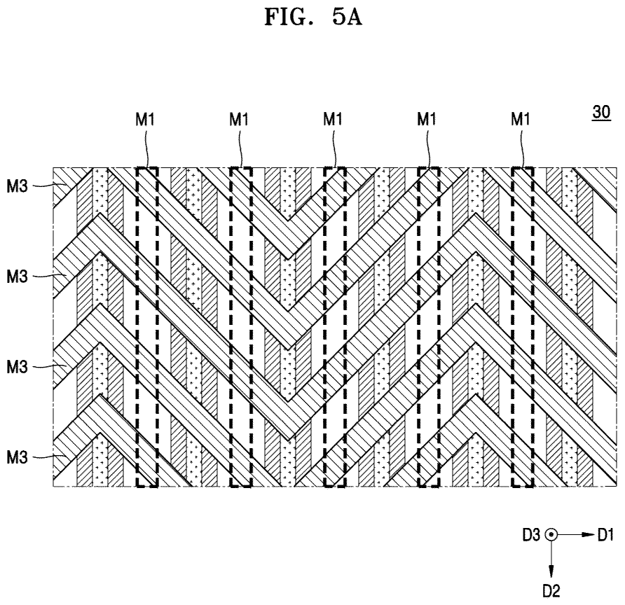

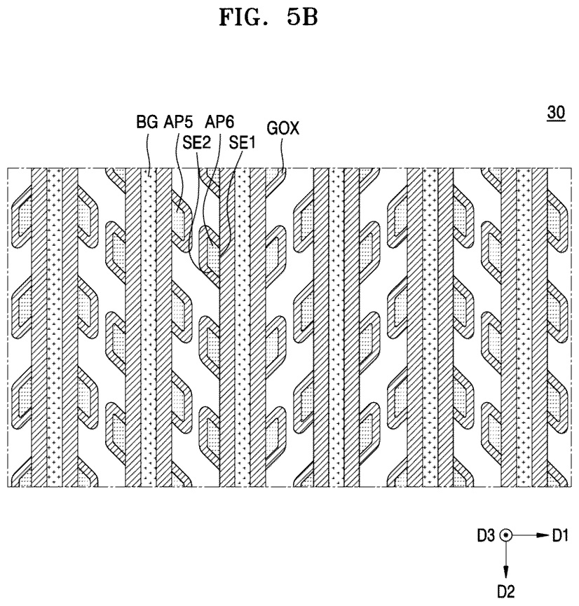

FIGS. 5A and 5B are layout diagrams schematically illustrating a semiconductor device 30 according to some example embodiments. Specifically, FIG. 5A is a layout diagram before etching an active pattern by covering a self-aligned mask M1 and a channel cut mask M3 after forming a back gate electrode BG, and FIG. 5B is a layout diagram after etching the active pattern and forming even a gate insulating pattern surrounding the active pattern in FIG. 5A.

Referring to FIGS. 5A and 5B, redundant description between the semiconductor device 30 of FIGS. 5A and 5B and the semiconductor device 10 of FIG. 1 will be omitted, and differences therebetween will be mainly explained.

The active pattern AP of the semiconductor device 30 may include a fifth active pattern AP5 and a sixth active pattern AP6. The shapes of the fifth active pattern AP5 and the sixth active pattern AP6 finally formed in FIG. 5B may be determined by the shapes of the self-aligned mask M1 and the channel cut mask M3 shown in FIG. 5A. The self-aligned mask M1 may be formed in a parallel bar shape, which extends in the second direction D2 and is spaced apart from each other at regular intervals in the first direction D1. The channel cut mask M3 may be formed in a zigzag shape. The zigzag shape may be a shape in which directions are bent for each of two channel pitches based on the first direction D1.

The fifth active pattern AP5 and the sixth active pattern AP6 may be alternately arranged on each bit line BL to face each other in a direction diagonal to the first direction D1. That is, the fifth active pattern AP5 and the sixth active pattern AP6 adjacent to each other may be arranged in a diagonal direction on the bit line BL in a plane view.

That is, the first surface and the second surface of the fifth active pattern AP5 may not completely overlap each other in terms of the first direction D1. The first surface and the second surface of the sixth active pattern AP6 may not completely overlap each other in terms of the first direction D1. By arranging the fifth active pattern AP5 and the sixth active pattern AP6 in the diagonal direction, the degree of integration of the semiconductor device 30 in the first direction D1 may be improved.

The fifth active pattern AP5 and the sixth active pattern AP6 may have a parallelogram shape in a plane view. The fifth active pattern AP5 and the sixth active pattern AP6 each may include a first side SE1 parallel to the second direction D2 and a second side SE2 parallel to the direction diagonal to the first direction D1. In some example embodiments, the first side SE1 may be longer than the second side SE2. In some example embodiments, the length of each of the second sides SE2 of the fifth active pattern AP5 and the sixth active pattern AP6 may be greater than the length of the bit line BL in the second direction D2.

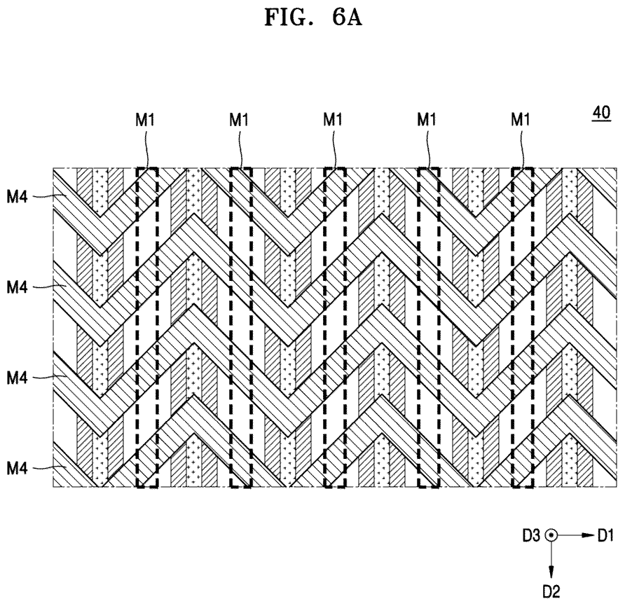

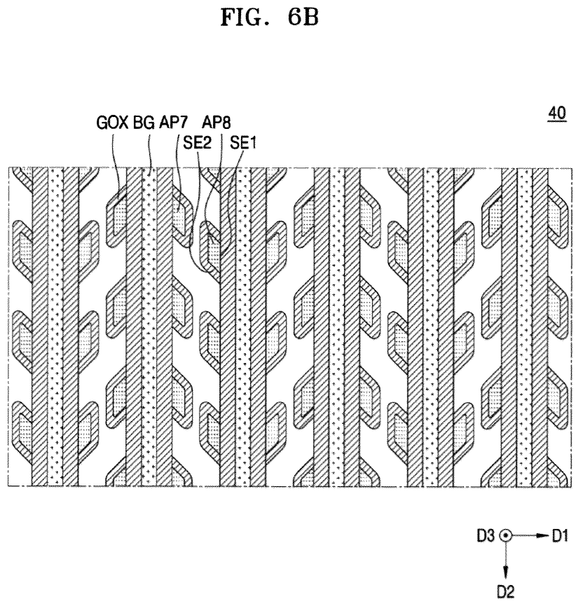

FIGS. 6A and 6B are layout diagrams schematically illustrating a semiconductor device 40 according to some example embodiments. Specifically, FIG. 6A is a layout diagram before etching an active pattern by covering a self-aligned mask M1 and a channel cut mask M4 after forming a back gate electrode BG, and FIG. 6B is a layout diagram after etching the active pattern and forming even a gate insulating pattern surrounding the active pattern in FIG. 6A.

Referring to FIGS. 6A and 6B, redundant description between the semiconductor device 40 of FIGS. 6A and 6B and the semiconductor device 10 of FIG. 1 will be omitted, and differences therebetween will be mainly explained.

The active pattern AP of the semiconductor device 40 may include a seventh active pattern AP7 and an eighth active pattern AP8. The shapes of the seventh active pattern AP7 and the eighth active pattern AP8 finally formed in FIG. 6B may be determined by the shapes of the self-aligned mask M1 and the channel cut mask M4 shown in FIG. 6A. The self-aligned mask M1 may be formed in a parallel bar shape extending in the second direction D2 and spaced apart from each other at regular intervals in the first direction D1. The channel cut mask M4 may be formed in a zigzag shape. The zigzag shape may be a shape in which directions are bent for each one channel pitch based on the first direction D1.

The seventh active pattern AP7 and the eighth active pattern AP8 may be alternately arranged on each bit line BL to face each other in a direction diagonal to the first direction D1. That is, the seventh active pattern AP7 and the eighth active pattern AP8 adjacent to each other may be arranged in a diagonal direction on the bit line BL in a plane view.

That is, the first surface and the second surface of the seventh active pattern AP7 may not completely overlap each other in the first direction D1. The first surface and the second surface of the eighth active pattern AP8 may not completely overlap each other in terms of the first direction D1. By arranging the seventh active pattern AP7 and the eighth active pattern AP8 in the diagonal direction, the degree of integration of the semiconductor device 40 in the first direction D1 may be improved.

The seventh active pattern AP7 and the eighth active pattern AP8 may have a parallelogram shape in a plane view. The seventh active pattern AP7 and the eighth active pattern AP8 each may include a first side SE1 parallel to the second direction D2 and a second side SE2 parallel to a direction diagonal to the first direction D1. In some example embodiments, the first side SE1 may be longer than the second side SE2. In some example embodiments, the length of each of the second sides SE2 of the seventh active pattern AP7 and the eighth active pattern AP8 may be greater than the length of the bit line BL in the second direction D2.

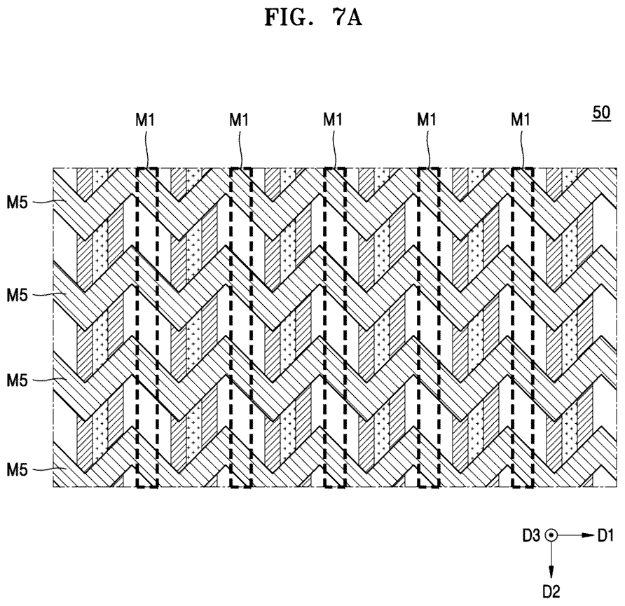

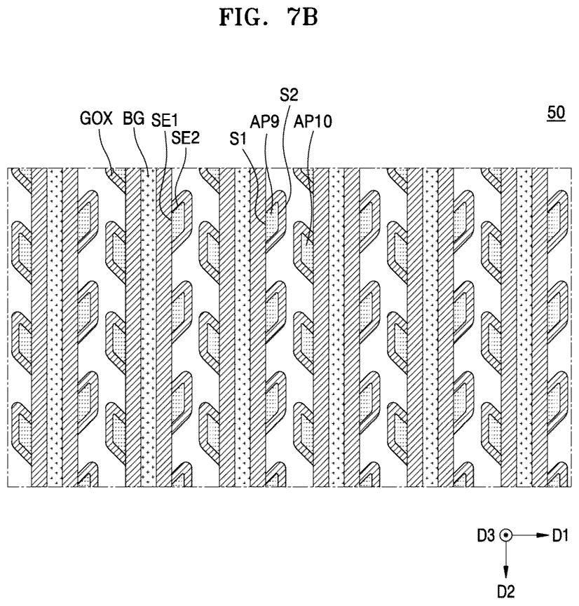

FIGS. 7A and 7B are layout diagrams schematically illustrating a semiconductor device 50 according to some example embodiments. Specifically, FIG. 7A is a layout diagram before etching an active pattern by covering a self-aligned mask M1 and a channel cut mask M5 after forming a back gate electrode BG, and FIG. 7B is a layout diagram after etching the active pattern and forming even a gate insulating pattern surrounding the active pattern in FIG. 7A.

Referring to FIGS. 7A and 7B, redundant description between the semiconductor device 50 of FIGS. 7A and 7B and the semiconductor device 10 of FIG. 1 will be omitted, and differences therebetween will be mainly explained.

The active pattern AP of the semiconductor device 50 may include a ninth active pattern AP9 and a tenth active pattern AP10. The shapes of the ninth active pattern AP9 and the tenth active pattern AP10 finally formed in FIG. 7B may be determined by the shapes of the self-aligned mask M1 and the channel cut mask M5 shown in FIG. 7A. The self-aligned mask M1 may be formed in a parallel bar shape, which extends in the second direction D2 and is spaced apart from each other at regular intervals in the first direction D1. The channel cut mask M5 may be formed in a zigzag shape. The zigzag shape may have a shape in which directions are bent at every half of a channel pitch interval based on the first direction D1.

The ninth active pattern AP9 and the tenth active pattern AP10 may be alternately arranged on each bit line BL to face each other in a direction diagonal to the first direction D1. That is, the ninth active pattern AP9 and the tenth active pattern AP10 adjacent to each other may be arranged in a diagonal direction on the bit line BL in a plane view.

That is, the first surface S1 and the second surface S2 of the ninth active pattern AP9 may not completely overlap each other in terms of the first direction D1. That is, the first surface S1 and the second surface S2 of the tenth active pattern AP10 may not completely overlap each other in terms of the first direction D1. By arranging the ninth active pattern AP9 and the tenth active pattern AP10 in a diagonal direction, the degree of integration of the semiconductor device 50 in the first direction D1 may be improved.

The ninth active pattern AP9 and the tenth active pattern AP10 may have a parallelogram shape in a plane view. The ninth active pattern AP9 and the tenth active pattern AP10 each may include a first side SE1 parallel to the second direction D2 and a second side SE2 parallel to a direction diagonal to the first direction D1. In some example embodiments, the first side SE1 may be longer than the second side SE2. In some example embodiments, the length of each of the second sides SE2 of the ninth active pattern AP9 and the tenth active pattern AP10 may be greater than the length of the bit line BL in the second direction D2.

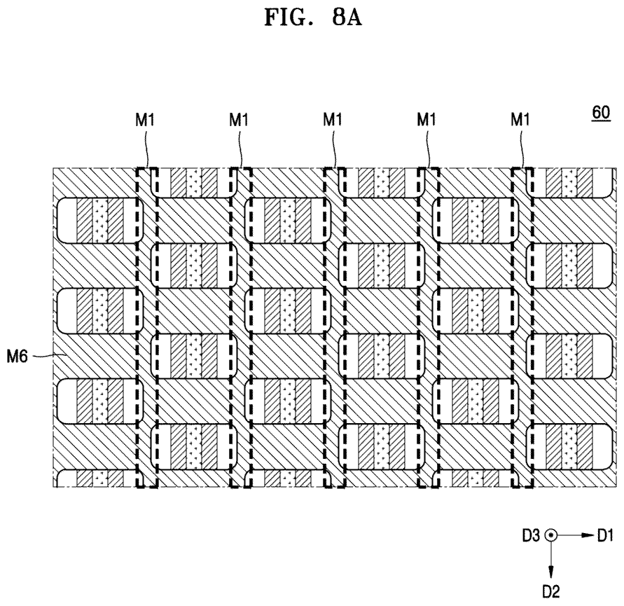

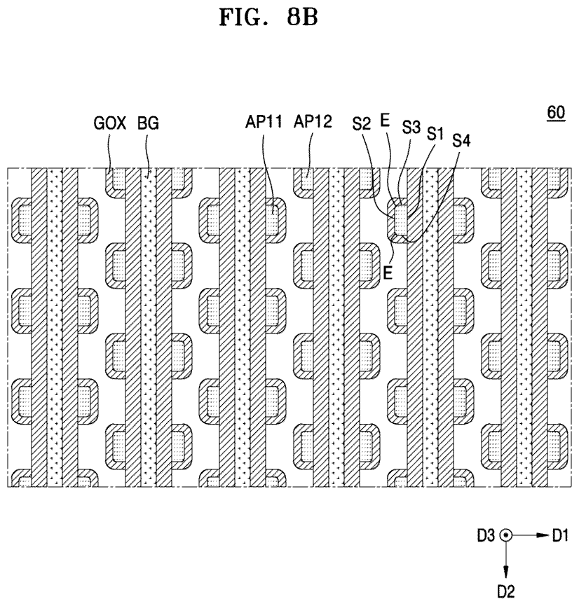

FIGS. 8A and 8B are layout diagrams schematically illustrating a semiconductor device 60 according to some example embodiments. Specifically, FIG. 8A is a layout diagram before etching an active pattern by covering a self-aligned mask M1 and a channel cut mask M6 after forming a back gate electrode BG, and FIG. 8B is a layout diagram after etching the active pattern and forming even a gate insulating pattern surrounding the active pattern in FIG. 8A.

Referring to FIGS. 8A and 8B, redundant description between the semiconductor device 60 of FIGS. 8A and 8B and the semiconductor device 10 of FIG. 1 will be omitted, and differences therebetween will be mainly explained.

The active pattern AP of the semiconductor device 60 may include an eleventh active pattern AP11 and a twelfth active pattern AP12. The shapes of the eleventh active pattern AP11 and the twelfth active pattern AP12 finally formed in FIG. 8B may be determined by the shapes of the self-aligned mask M1 and the channel cut mask M6 shown in FIG. 8A. The self-aligned mask M1 may be formed in a parallel bar shape extending in the second direction D2 and spaced apart from each other at regular intervals in the first direction D1. The channel cut mask M6 may have a shape repeatedly having rectangular holes having rounded edges in a direction diagonal to the first direction D1 on a wide plate.

The eleventh active pattern AP11 and the twelfth active pattern AP12 each may be alternately arranged on each bit line BL to face each other in a direction diagonal to the first direction D1. That is, the eleventh active pattern AP11 and the twelfth active pattern AP12 adjacent to each other may be arranged in a diagonal direction on the bit line BL in a plane view.

Among the edges E of the eleventh active pattern AP11 and the twelfth active pattern AP12, edges extending in the third direction in contact with the gate insulating pattern GOX may have a rounded shape. That is, when the eleventh active pattern AP11 and the twelfth active pattern AP12 are viewed on a plane (e.g., a plane extending in the first direction D1 and the second direction D2), a side of the active pattern AP facing the word line WL may have a rounded shape. In other words, the third surface S3 and the fourth surface S4 perpendicular to the second surface S2 and spaced apart from each other in the second direction D2 may be connected to the second surface S2 in a curved line. In some example embodiments, the edge E where the second surface S2 and the third surface S3 meet may be a round surface that extends longitudinally in the third direction and has a particular (or, alternatively, predetermined) curvature.

The second surface S2 may be a curved surface convex toward the word line WL, and the first surface S1 may be a plane (e.g., a plane extending in the second direction D2 and the third direction D3). In other words, the eleventh active pattern AP11 and the twelfth active pattern AP12 may have a shape in which the thicknesses of the eleventh active pattern AP11 and the twelfth active pattern AP12 in the second direction D2 decrease from the first surface to the second surface. By arranging the eleventh active pattern AP11 and the twelfth active pattern AP12 in the diagonal direction, the degree of integration of the semiconductor device 60 in the first direction D1 may be improved.

Although not illustrated in the drawings, the semiconductor devices 10, 20, 30, 40, 50, and 60 according to some example embodiments may further include peripheral circuit devices and inter-wiring insulating layers.

The peripheral circuit devices and the inter-wiring insulating layers may be formed on the substrate of the semiconductor devices 10, 20, 30, 40, 50, and 60. The peripheral circuit devices include control devices and dummy devices to control functions of the semiconductor devices 10, 20, 30, 40, 50, and 60 formed on the substrate 100. The inter-wiring insulating layers may cover the peripheral circuit devices.

In some example embodiments, the peripheral circuit devices may further include a plurality of conductive patterns (not shown) formed on the top surface of the substrate. The plurality of conductive patterns may constitute various circuit devices for controlling functions of the semiconductor devices 10, 20, 30, 40, 50, and 60. For example, peripheral circuit devices may include various passive elements such as capacitors, resistors, and inductors, as well as various active elements such as transistors.

In some example embodiments, the peripheral circuit devices and the inter-wiring insulating layers may be arranged below the gate insulating pattern GOX. That is, the semiconductor device according to some example embodiments may have a cell on peri (COP) structure.

In some example embodiments, the peripheral circuit devices may be connected to the bit lines BL. Accordingly, the bit lines BL may be controlled by the peripheral circuit devices.

While the inventive concepts have been particularly shown and described with reference to some example embodiments thereof, it will be understood that various changes in form and details may be made therein without departing from the spirit and scope of the following claims.

What is claimed is:

1. A semiconductor device, comprising:
a substrate;
a bit line extending in a first direction on the substrate;
a first active pattern and a second active pattern on the bit line;
a back gate electrode extending in a second direction perpendicular to the first direction across the bit line; and
a word line extending in the second direction,
wherein the first active pattern and the second active pattern have a mirror symmetrical shape with respect to the back gate electrode when viewed in a third direction perpendicular to the first direction and the second direction.

2. The semiconductor device of claim 1, wherein the first active pattern and the second active pattern are alternately on the bit line to face each other in a direction diagonal to the first direction.

3. The semiconductor device of claim 1, wherein
the first active pattern and the second active pattern each comprise a first surface facing the back gate electrode and a second surface facing the word line, and
the first surface is a plane, and opposite ends of the second surface are curved surfaces in a convex shape toward the word line.

4. The semiconductor device of claim 1, further comprising a gate insulating pattern surrounding the first active pattern and the second active pattern.

5. The semiconductor device of claim 1, wherein the first active pattern and the second active pattern have parallelogram shapes each including a first side parallel to the second direction and a second side parallel to a direction diagonal to the first direction.

6. The semiconductor device of claim 5, wherein the first side is longer than the second side.

7. The semiconductor device of claim 1, wherein an uppermost surface of the first active pattern is coplanar with an uppermost surface of the second active pattern.

8. The semiconductor device of claim 1, wherein a length of each of the first active pattern and the second active pattern in the second direction is greater than a length of the bit line in the second direction.

9. A semiconductor device, comprising:
a substrate;
a plurality of bit lines extending in a first direction on the substrate and spaced apart from each other in a second direction perpendicular to the first direction;
a plurality of first active patterns and a plurality of second active patterns on the plurality of bit lines;
a back gate electrode between the plurality of first active patterns and the plurality of second active patterns and extending in the second direction across the plurality of bit lines;
a first word line extending in the second direction on one side of the plurality of first active patterns; and
a second word line extending on one side of the plurality of second active patterns in the second direction and spaced apart from the first word line in the first direction with the plurality of first active patterns, the back gate electrode, and the plurality of second active patterns therebetween,
wherein each of the plurality of first active patterns and the plurality of second active patterns has a minor symmetrical shape with respect to the back gate electrode when viewed from a third direction perpendicular to the first direction and the second direction.

10. The semiconductor device of claim 9, wherein the first word line comprises a protrusion protruding from a body toward the back gate electrode to fill a space between adjacent first active patterns of the plurality of first active patterns.

11. The semiconductor device of claim 10, wherein
the plurality of first active patterns are spaced apart from each other by a first interval in the second direction, and
the plurality of second active patterns are spaced apart from each other by a second interval in the second direction.

12. The semiconductor device of claim 11, wherein the second interval is a same interval as the first interval.

13. The semiconductor device of claim 9, wherein the plurality of first active patterns and the plurality of second active patterns are alternately arranged on the plurality of bit lines to face each other in a direction diagonal to the first direction.

14. The semiconductor device of claim 9, wherein
each of the plurality of first active patterns comprises a first surface facing the back gate electrode and a second surface facing the first word line,
each of the plurality of second active patterns comprises a first surface facing the back gate electrode and a second surface facing the first word line,
all of the first surfaces of the plurality of first active patterns and the first surfaces of the plurality of second active patterns are planar,
opposite ends of the second surface of each of the plurality of first active patterns are curved surfaces in a convex form toward the first word line, and
opposite ends of the second surface of each of the plurality of second active patterns are curved surfaces in a convex form toward the second word line.

15. The semiconductor device of claim 9, further comprising a gate insulating pattern surrounding the plurality of first active patterns and the plurality of second active patterns.

16. The semiconductor device of claim 9, wherein the plurality of first active patterns and the plurality of second active patterns have parallelogram shapes each including a first side parallel to the second direction and a second side parallel to a direction diagonal to the first direction.

17. The semiconductor device of claim 16, wherein the first side is longer than the second side.

18. The semiconductor device of claim 9, wherein a length of each of the plurality of first active patterns and the plurality of second active patterns in the second direction is greater than a length of each of the plurality of bit lines in the second direction.

19. A semiconductor device, comprising:
a substrate;
a plurality of bit lines extending in a first direction on the substrate and spaced apart from each other in a second direction perpendicular to the first direction,
a plurality of first active patterns on the plurality of bit lines;
a plurality of second active patterns on the plurality of bit lines;
a back gate electrode between the plurality of first active patterns and the plurality of second active patterns and extending in the second direction across the plurality of bit lines;
a first word line extending in the second direction on one side of the plurality of first active patterns;
a second word line extending on one side of the plurality of second active patterns in the second direction and spaced apart from the first word line in the first direction with the plurality of first active patterns, the back gate electrode, and the plurality of second active patterns therebetween; and
a gate insulating pattern surrounding the plurality of first active patterns and the plurality of second active patterns,
wherein each of the plurality of first active patterns includes a first surface facing the back gate electrode and a second surface facing the first word line,
wherein each of the plurality of second active patterns includes a first surface facing the back gate electrode and a second surface facing the second word line,
wherein the second surface of each first active pattern of the plurality of first active patterns includes a part rounded to gradually approach the back gate electrode as the second surface of the first active pattern approaches opposite ends of the second surface of the first active pattern in the second direction,
the second surface of each second active pattern of the plurality of second active patterns includes a part rounded to gradually approach the back gate electrode as the second surface of the second active pattern approaches opposite ends of the second surface of the second active pattern in the second direction,
the first word line includes a first protrusion portion between adjacent first active patterns of the plurality of first active patterns in the second direction, and
the second word line includes a second protrusion portion between adjacent second active patterns of the plurality of second active patterns in the second direction.

20. The semiconductor device of claim 19, wherein
the plurality of first active patterns and the plurality of second active patterns are alternately on the plurality of bit lines to face each other in a direction diagonal to the first direction, and
an interval at which the plurality of first active patterns are spaced apart in the second direction is a same interval as an interval at which the plurality of second active patterns are spaced apart in the second direction.
